(19) United States
(12) Patent Application Publication
(10) Pub. No.: US 2003/0082923 A1
(43) Pub. Date: May 1, 2003

(54) Method and apparatus for radical oxidation of silicon

(76) Inventor: Yoshi Ono, Camas, WA (US)

Correspondence Address: David C. Ripma, Patent Counsel, Sharp Laboratories of America, Inc., 5750 NW Pacific Rim Boulevard, Camas, WA, 98607, US

(21) Appl. No.: 10/020,424

(22) Filed: Oct. 30, 2001

(51) Int. Cl. H01L 21/31; H01L 21/469

(52) U.S. Cl. 438/771; 438/788

(57) ABSTRACT

An apparatus for radical oxidation of a silicon wafer contained therein includes a vacuum chamber having a heated chuck therein for holding the silicon wafer, and for maintaining the temperature of the silicon wafer at a temperature of between about 400° C. to 500° C.; an oxidation gas source for providing an oxygen-containing gas to oxidize the silicon wafer in the vacuum chamber; an oxygen dissociation mechanism for dissociating the oxygen-containing gas into a dissociation product containing oxygen in a O(1D) state; and a mechanism for moving the dissociation product through the vacuum chamber. A method of radical oxidation of silicon wherein the silicon is in the form of a wafer of semiconductor-pure silicon includes placing a silicon wafer in a heated chuck, wherein the heated chuck maintains the silicon wafer therein at a temperature of between about 400° C. and 500° C., and wherein the heated chuck is contained in a vacuum chamber, which is maintained at a pressure of between about one mTorr. and 2000 mTorr; introducing an oxidizing gas into an oxygen dissociation mechanism; dissociating the oxidizing gas into a dissociated product containing oxygen in a O(1D) state; passing the oxygen in its O(1D) state over the heated silicon wafer; and maintaining the silicon wafer in the vacuum chamber for a period time of between about one minute and sixty minutes to form a layer of silicon dioxide on the wafer.

### FIELD OF THE INVENTION

This invention relates to the fabrication of integrated circuits on silicon, and specifically to the formation of a low temperature, high quality silicon dioxide layer formed by the oxidation of silicon.

### BACKGROUND OF THE INVENTION

Conventional techniques for the oxidation of silicon require high temperatures, i.e., greater than 800° C., for long periods of time, in an oxidizing ambient, such as NO₂, O₂, or NO. During such oxidation, diffusion of elements occurs within the substrate, and semiconductor fabrication sequences must be tailored to accommodate such diffusion.

An efficient method of oxidizing silicon at low temperatures for manufacturing purposes currently does not exist. There are known methods of oxidizing silicon at low temperatures such as plasma oxidation, as described by K. Watanabe, et al., Controlling the concentration and position of nitrogen in ultrathin oxynitride films formed by using oxygen and nitrogen radicals, Appl. Phys. Lett. 76, 2940 (2000); or oxidation with a radial slot line antennae, as described in Y. Saito, et al., Advantage of Radical Oxidation for Improving Reliability of Ultra-Thin Gate Oxide, 2000 Symposium on VLSI Technology, T18-2, (2000); and by M. Hirayama, et al, Low Temperature Growth of High-Integrity Silicon Oxide Films by Oxygen Radical Generated in High Density Krypton Plasma, IEDM Tech. Dig. p249, (1999). These methods produce large quantities of ions as well as radicals, which ions can damage the silicon surface and degrade the quality of the oxide layer.

V. Nayar, et al., Atmospheric Pressure, Low Temperature (<500° C.) UV/Ozone Oxidation of Silicon, Electronics Letters, 26, 205 (1990), describe a technique wherein UV and ozone are combined to generate oxygen radicals, however, the atmospheric pressure used in their system allows O(1D) to collisionally deactivate to the O(3P) state. The obtained results are severely handicapped by the lack of the O(1D). Nevertheless, enhanced oxidation rates and good stoichiometric oxide are reported.

Other techniques are described in R. J. Wilson, et al., Speed-Dependent Anisotropy Parameters in the UV Photodissociation of Ozone, J. Phys. Chem. A, 101, 7593-7599 (1997); and by K. Takahashi, et al., Wavelength and temperature dependence of the absolute O(1D) production yield from the 305-329 nm photodissociation of ozone, J. Chem. Phys. 108, 7161 (1998).

The ability to perform an oxidation at much lower temperatures without sacrificing substrate quality will be a tremendous benefit to the semiconductor industry. The oxidation rate on (100) silicon (square plane orientation) is practically the same as for (111) silicon (triangular plane orientation), so such an oxidation technique will immediately address the need for conformal oxidation for shallow trench isolation.

### SUMMARY OF THE INVENTION

An apparatus for radical oxidation of a silicon wafer contained therein includes a vacuum chamber having a heated chuck therein for holding the silicon wafer, and for maintaining the temperature of the silicon wafer at a temperature of between about 400° C. to 500° C.; an oxidation gas source for providing an oxygen-containing gas to oxidize the silicon wafer in the vacuum chamber; an oxygen dissociation mechanism for dissociating the oxygen-containing gas into a dissociation product containing oxygen in a O(1D) state; and a mechanism for moving the dissociation product through the vacuum chamber.

A method of radical oxidation of silicon wherein the silicon is in the form of a wafer of semiconductor-pure silicon includes placing a silicon wafer in a heated chuck, wherein the heated chuck maintains the silicon wafer therein at a temperature of between about 400° C. and 500° C., and wherein the heated chuck is contained in a vacuum chamber, which is maintained at a pressure of between about one mTorr. and 2000 mTorr; introducing an oxidizing gas into an oxygen dissociation mechanism; dissociating the oxidizing gas into a dissociated product containing oxygen in a O(1D) state; passing the oxygen in its O(1D) state over the heated silicon wafer; and maintaining the silicon wafer in the vacuum chamber for a period time of between about one minute and sixty minutes to form a layer of silicon dioxide on the wafer.

It is an object of the invention to provide a method of rapidly oxidizing a silicon substrate to form a silicon dioxide layer at a relatively low temperature;

Another object of the invention is to provide an apparatus for carrying out the method of the invention.

A further object of the invention is to oxidize a silicon wafer without causing diffusion of undesirable elements into the silicon substrate.

This summary and objectives of the invention are provided to enable quick comprehension of the nature of the invention. A more thorough understanding of the invention may be obtained by reference to the following detailed description of the preferred embodiment of the invention in connection with the drawings.

### BRIEF DESCRIPTION OF THE DRAWINGS

FIG. 1 depicts the apparatus for performing radical oxygen oxidation of silicon.

FIG. 2 depicts an alternate embodiment of the apparatus of the invention.

FIG. 3 depicts an alternate embodiment of the apparatus of the invention for performing radical oxidation with a UV laser.

### DETAILED DESCRIPTION OF THE PREFERRED EMBODIMENT

The method of the invention includes generation of large quantities of a radical oxygen atom, specifically oxygen atoms in the O(1D) metastable state. It is known that this oxygen atom can be produced by photodissociation of O₃ or N₂O. Ozone (O₃) irradiated with ultraviolet light of wavelengths less than 311 nm produces O(1D). Similarly, N₂O irradiated with ultraviolet light of wavelengths less than 195 nm also produces O(1D). By virtue of the fact that this O(1D) state has a higher energy than the ground state, O(3P), it will oxidize silicon faster and with greater efficiency than oxygen at the ground state.

The metastable O(1D) state may easily be deactivated through collisions with other molecules or may react with impurities. Thus it is important that this species is not quenched prior to reaching the silicon surface which is to be oxidized. This necessitates that the oxidation process be carried out in a low pressure vacuum chamber environment, preferably in a quartz lined system.

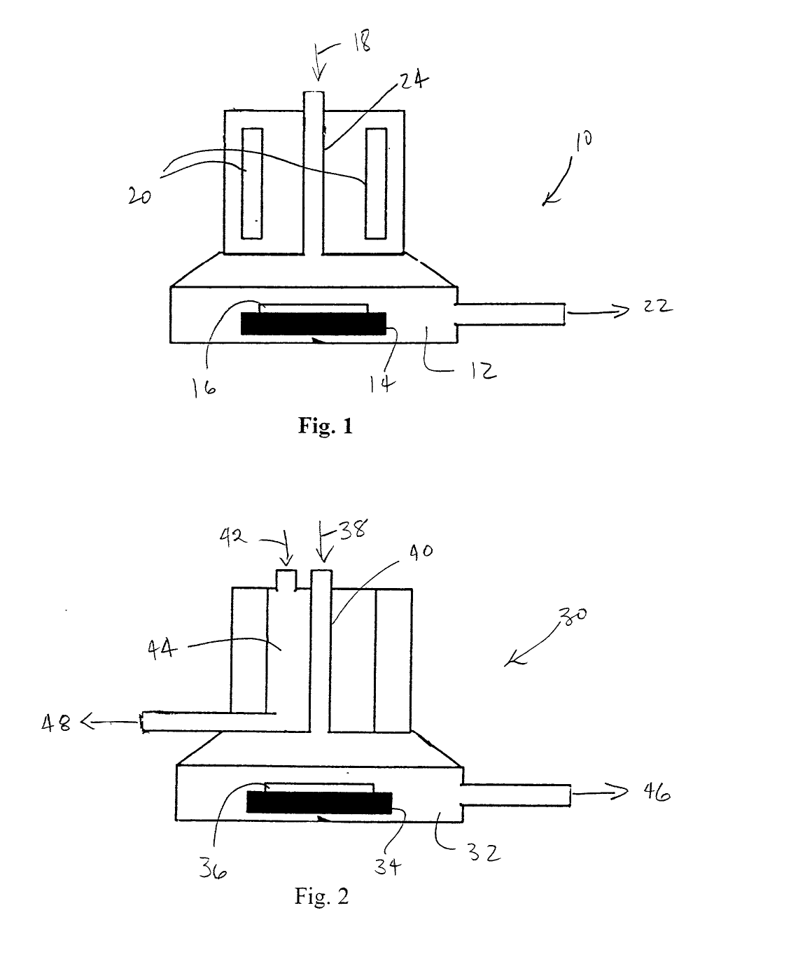

The apparatus of the first preferred embodiment illustrated in FIG. 1, generally at 10, and includes a vacuum chamber 12, having a heated chuck 14 therein. A silicon wafer 16 is placed in chuck 14 where it sits during the oxidation process. An oxidation gas source 18 provides a gas which may be dissociated to form oxygen in a O(1D) state, such as O₂, O₃, or N₂O. In this embodiment, an oxygen dissociation mechanism 20 includes an ultraviolet-producing light source, which has a high ultraviolet light concentration, such as a mercury vapor lamp or excimer lamp. A pump 22 provides a mechanism for moving the dissociated oxidation gas through and for evacuating the dissociated oxidation gas from chamber 12. Gas source 18 introduces a flow of either oxidation gas into vacuum chamber 12 through a quartz tube 24, which is roughly one inch in diameter. This tube passes through a region irradiated by light from light source 20. The photodissociated product, containing O(1D), is allowed to flow to the surface of a heated wafer, held in a chuck. The temperature for oxidation may be as low as between about 400° C. to 500° C., however, the oxidation rate is equivalent to that of O₂ thermal oxidation conducted at 1000° C. The pressure in chamber 12 is maintained at between about one mTorr. to 2000 mTorr., and the oxidation process takes between about one minute to sixty minutes.

Other research performed along these lines have generated the O(1D) along with many other excited and ionized molecules. The most relevant case is described by Saito, et al., supra, wherein a mixture of Kr and O₂ in a plasma discharge so that the excited Kr* will undergo a resonant energy transfer to form O₂* that will dissociated forming O(1D) is described. The O(1D), along with the other excited and ionized species will interact with the silicon surface to form an oxide.

Another configuration for performing the method of the invention is illustrated in FIG. 2, generally at 30. Apparatus 30 includes a vacuum chamber 32, a heated chuck 34, a silicon wafer 36, a first, oxidation gas source 38, a quartz delivery tube 40 for the oxidation gas, a second, plasma gas source 42, and an inductively coupled plasma generator 44, which generates a plasma from a gas which emits strong UV radiation, such as He or Ar. A first pump 46 draws the dissociated oxidation gas out of chamber 32, while a second pump 48 draws the plasma gas out of inductively coupled plasma generator 44. Typical operating conditions for He may be between about 30 mTorr. to 70 mTorr., at a flow of about 10 sccm, using a 13.56 MHz RF generator operated at between about 200 Watts to 700 Watts. The oxidizing gas is separated from the plasma gas and will not generate its own discharge because the pressure is much greater than that needed for breakdown conditions. The optical coupling between the plasma and the oxidizing gas enables the formation of O(1D) species. The pressure in chamber 32 is maintained at between about one mTorr. to 2000 mTorr., and the oxidation process takes between about one minute to sixty minutes.

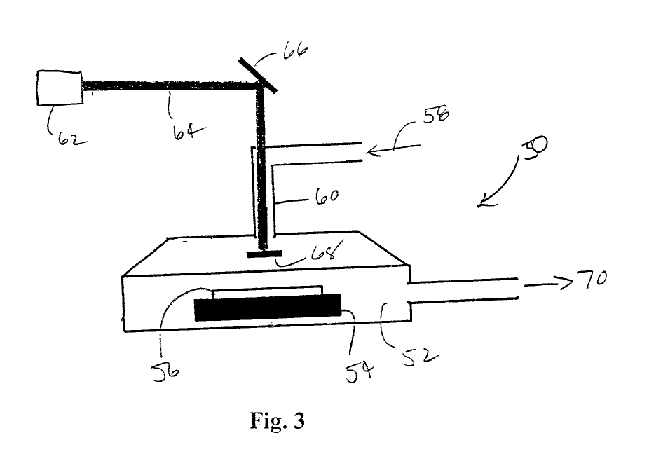

Apparatus 50, the third preferred embodiment of the invention is depicted in FIG. 3. Apparatus 50 includes a vacuum chamber 52, a heated chuck 54, a silicon wafer 56, an oxidation gas source 58 and a quartz delivery tube 60. A laser 62 generates a laser beam 64, which is deflected off a mirror 66 into tube 60, and is reflected back into tube 60 by mirror 68. A pump 70 is operable to evacuate the dissociated oxidation gas from chamber 52. Laser beam 64 is used to dissociate the oxidation gas into a dissociation product containing oxygen in the O(1D) state. The laser may be either a pulsed or continuous wave (CW) variety, so long as the output wavelength is sufficiently short to perform the desired photodissociation. A pulsed excimer laser of ArF, for example, generates an ultraviolet light output having a wavelength of about 193 nm, which is sufficient to break apart N₂O molecules, forming O(1D). A CW laser such as a krypton ion laser, tuned to its 406.7 nm line can photodissociate O₃ to form O(1D). The length of gas flow and laser path should be optimized along with the gas flow rate to achieve maximum oxidation efficiency. The pressure in chamber 52 is maintained at between about one mTorr. to 2000 mTorr., and the oxidation process takes between about one minute to sixty minutes.

Thus, a method and system for radical oxidation of silicon has been disclosed. It will be appreciated that further variations and modifications thereof may be made within the scope of the invention as defined in the appended claims.

I claim:

1. An apparatus for radical oxidation of a silicon wafer contained therein, comprising:
a vacuum chamber having a heated chuck therein for holding the silicon wafer, and for maintaining the temperature of the silicon wafer at a temperature of between about 400° C. to 500° C.;
an oxidation gas source for providing an oxygen-containing gas to oxidize the silicon wafer in the vacuum chamber;
an oxygen dissociation mechanism for dissociating the oxygen-containing gas into a dissociation product containing oxygen in a O(1D) state; and
a mechanism for moving the dissociation product through the vacuum chamber.

2. The apparatus of claim 1 wherein the oxygen-containing gas is taken from the group of oxygen-containing gases consisting of O₂, O₃ and N₂O.

3. The apparatus of claim 1 wherein the oxygen dissociation mechanism includes an ultraviolet light source, including a mercury vapor lamp.

4. The apparatus of claim 1 wherein the oxygen dissociation mechanism includes an ultraviolet light source, including an excimer lamp.

5. The apparatus of claim 1 wherein the oxygen dissociation mechanism includes an ultraviolet light source, including an inductively coupled plasma generator.

6. The apparatus of claim 5 wherein said inductively coupled plasma generator includes a plasma gas source, including a gas source providing an ultraviolet-producing plasma gas taken from the group of plasma gases consisting of He and Ar, and an RF generator for operating at a frequency of about 13.56 MHz at a power of between about 200 watts to 700 watts, wherein the inductively coupled plasma generator operates at an internal pressure of between about 30 mTorr. to 70 mTorr.

7. The apparatus of claim 1 wherein the oxygen dissociation mechanism includes an ultraviolet light source, including a laser beam generator.

8. The apparatus of claim 7 wherein said laser beam generator is a pulsed ArF excimer laser which generates a beam having a wavelength of about 193 nm.

9. The apparatus of claim 7 wherein said laser beam generator is a continuous wave Kr laser which generates a beam having a wavelength of about 406.7 nm.

10. A method of radical oxidation of silicon wherein the silicon is in the form of a wafer of semiconductor-pure silicon, comprising:
placing a silicon wafer in a heated chuck, wherein the heated chuck maintains the silicon wafer therein at a temperature of between about 400° C. and 500° C., and wherein the heated chuck is contained in a vacuum chamber, which is maintained at a pressure of between about one mTorr. and 2000 mTorr;
introducing an oxidizing gas into an oxygen dissociation mechanism;
dissociating the oxidizing gas into a dissociated product containing oxygen in a O(1D) state;
passing the oxygen in its O(1D) state over the heated silicon wafer; and
maintaining the silicon wafer in the vacuum chamber for a period time of between about one minute and sixty minutes to form a layer of silicon dioxide on the wafer.

11. The method of claim 10 wherein said introducing includes introducing an oxidizing gas taken from the group of oxidizing gases consisting of O₂, O₃ and N₂O.

12. The method of claim 10 wherein said dissociating the oxidizing gas into a dissociated product includes exposing the oxidizing gas to ultraviolet radiation of a wavelength of between about 195 nm and 311 nm, wherein the ultraviolet radiation is generated by an ultraviolet light source.

13. The method of claim 12 wherein said dissociating the oxidizing gas into a dissociated product includes generating an ultraviolet light source with a mercury vapor light.

14. The method of claim 12 wherein said dissociating the oxidizing gas into a dissociated product includes generating an ultraviolet light source with an excimer light.

15. The method of claim 12 wherein said dissociating the oxidizing gas into a dissociated product includes generating an ultraviolet light source with an inductively coupled plasma generator.

16. The method of claim 15 wherein said dissociating includes providing an inductively coupled plasma generator which includes a plasma gas source, including a gas source providing an ultraviolet-producing plasma gas taken from the group of plasma gases consisting of He and Ar, and an RF generator for operating at a frequency of about 13.56 MHz at a power of between about 200 watts to 700 watts, wherein the inductively coupled plasma generator operates at an internal pressure of between about 30 mTorr. to 70 mTorr.

17. The method of claim 12 wherein said dissociating the oxidizing gas into a dissociated product includes generating an ultraviolet light source with a laser beam generator.

18. The method of claim 17 wherein said dissociating the oxidizing gas into a dissociated product includes generating an ultraviolet light source with laser beam generator includes a pulsed ArF excimer laser which generates a beam having a wavelength of about 193 nm.

19. The method of claim 17 wherein said dissociating the oxidizing gas into a dissociated product includes generating an ultraviolet light source with laser beam generator includes a continuous wave Kr laser which generates a beam having a wavelength of about 406.7 nm.
